(19) United States
(12) Patent Application Publication
(10) Pub. No.: US 2008/0106189 A1
(43) Pub. Date: May 8, 2008

(54) ORGANIC ELECTRO-LUMINESCENT DISPLAY AND METHOD OF MANUFACTURING THE SAME

(75) Inventors: Ki-deok Bae, Yongin-si (KR); Chang-seung Lee, Yongin-si (KR); Chan-bong Jun, Yongin-si (KR)

Correspondence Address: CANTOR COLBURN, LLP, 20 Church Street, 22nd Floor, Hartford, CT, 06103, US

(73) Assignee: Samsung Electronics Co., Ltd., Suwon-si (KR)

(21) Appl. No.: 11/780,084

(22) Filed: Jul. 19, 2007

(30) Foreign Application Priority Data
Nov. 3, 2006 (KR) 10-2006-0108535

(51) Int. Cl. H01J 1/62; H01J 17/49; H01L 51/54; H01L 51/56

(52) U.S. Cl. 313/504; 430/5

(57) ABSTRACT

An organic electro-luminescent display (“OELD”) and a method of manufacturing the OELD include: a substrate; a plurality of anodes substantially parallel with one another in a first direction and disposed on the substrate; a plurality of cathodes disposed substantially parallel with one another in a second direction orthogonal to the plurality of anodes; organic electro-luminescent parts disposed at intersections between the anodes and the cathodes; and cathode separators disposed between the cathodes. Upper portions of the cathode separators are wider than lower portions of the cathode separators; and protrusions protrude from sides of the upper portions of the cathode separators.

This application claims priority to Korean Patent Application No. 10-2006-0108535, filed on Nov. 3, 2006, and all the benefits accruing therefrom under 35 U.S.C. § 119, the contents of which in its entirety are herein incorporated by reference.

### BACKGROUND OF THE INVENTION

1. Field of the Invention

The present invention relates to an organic electro-luminescent display (“OELD”) and a method of manufacturing the same, and more particularly, to a cathode separator of an OELD and a method of manufacturing the same.

2. Description of the Related Art

U.S. Pat. Pub. No. 2005/00116629 to Takamura et al. (hereinafter “Takamura”) discloses a passive matrix type organic electro-luminescent display (OELD) using a cathode separator. The cathode separator separates adjacent cathodes from each other and prevents a short-circuit between the adjacent cathodes.

In manufacturing the cathodes, as in Takamura, the cathode separator is first formed, and then a cathode material is deposited on the cathode separator. The cathode separator has a cross-sectional profile that is narrower at a bottom surface thereof (e.g., the surface disposed on the anode separator in Takamura) than a top surface of the cathode separator, thus providing a cathode separator cross-section that is inverse-trapezoidal in shape. Because the opposing sides of the cathode separator slope inwardly with respect to the substrate, formation of a cathode material on either of the opposing sides of the cathode separator is discouraged. As a result, the cathode material is separated into strips. Even still, cathode material can form on the sides of the cathode separator.

Accordingly, the successful separation of cathodes is required to preclude short-circuits between adjacent cathodes. If cathode material contacts the sides of the cathode separators, short-circuits between cathodes can result, degrading OELD performance. Therefore, successful manufacture of passive matrix type OELD devices is dependent on discouraging formation of cathode material on the sides of the cathode separators.

### BRIEF SUMMARY OF THE INVENTION

The present invention provides an organic electro-luminescent display (OELD) capable of effectively preventing a short-circuit between adjacent cathodes and a method of manufacturing the OELD.

According to an exemplary embodiment of the present invention, provided is an OELD including a substrate; a plurality of anodes disposed on the substrate substantially parallel with one another in a first direction; a plurality of cathodes disposed substantially parallel with one another in a second direction orthogonal to the plurality of anodes; organic electro-luminescent parts disposed at intersections between the anodes and the cathodes; a plurality cathode separators disposed between the cathodes, each of the cathode separators having an upper portion and a lower portion, the upper portions of the cathode separators are wider than lower portions of the cathode separators, wherein protrusions protrude from sides of the upper portions of the cathode separators.

The sides of the cathode separators may slope inwardly with respect to the substrate, thus providing cathode separators with an inverse-trapezoidal cross-sectional shape, and the protrusions of the cathode separators can protrude from an upper portion of the cathode separators.

According to another embodiment of the present invention, provided is a method of manufacturing an OELD. The method includes disposing a plurality of anodes on a substrate substantially parallel with one another in a first direction; forming a photoresist on the substrate; differentially exposing the photoresist at least two times to form cathode separators each having an upper portion and a lower portion having different widths, the width of the upper portion is wider than the width of the lower portion; developing the photoresist to form the cathode separators; and forming a plurality of strip-shaped cathodes between the cathode separators, the cathodes being substantially parallel with one another in a direction orthogonal to the first direction.

The differentially exposing of the photoresist layer may further include adjusting a distance between the photoresist layer and a mask to form the upper and lower portions having the different widths using the mask.

The mask may be spaced apart from the photoresist layer to perform the exposure for forming the upper portion of the cathode separator, and the mask may approach or contact the photoresist layer to perform the exposure for forming the lower portion of the cathode separator.

The upper and lower portions of the cathode separator may be formed using masks having openings with different widths.

### BRIEF DESCRIPTION OF THE DRAWINGS

The above and other aspects, features and advantages of the present invention will become more apparent by describing in further detail exemplary embodiments thereof with reference to the attached drawings, wherein like elements are numbered alike, in which:

FIG. 1 is a schematic partial plan view illustrating a layout of an organic electro-luminescent display (“OELD”) according to an exemplary embodiment of the present invention;

FIG. 2 is a schematic partial perspective view of the OELD of FIG. 1;

FIG. 3 is partial enlarged cross-sectional view of a portion of a cathode separator adopted in an OELD according to an exemplary embodiment of the present invention;

FIGS. 4A through 4G are partial cross-sectional views illustrating a method of manufacturing an OELD according to an exemplary embodiment of the present invention; and

FIGS. 5A and 5B are partial cross-sectional views illustrating an exposure process for forming a cathode separator in a method of manufacturing an OELD according to another exemplary embodiment of the present invention.

### DETAILED DESCRIPTION OF THE INVENTION

The present invention will now be described in greater detail with reference to the accompanying drawings.

It will be understood that when an element is referred to as being “on” another element, it can be directly on the other element or intervening elements may be present therebetween. In contrast, when an element is referred to as being “disposed on” or “formed on” another element, the elements are understood to be in at least partial contact with each other, unless otherwise specified.

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but is included to identify individual elements. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements and the thicknesses of layers and regions are exaggerated for clarity.

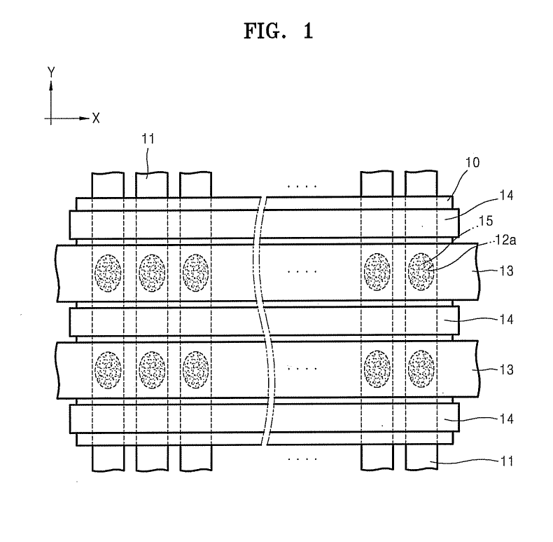

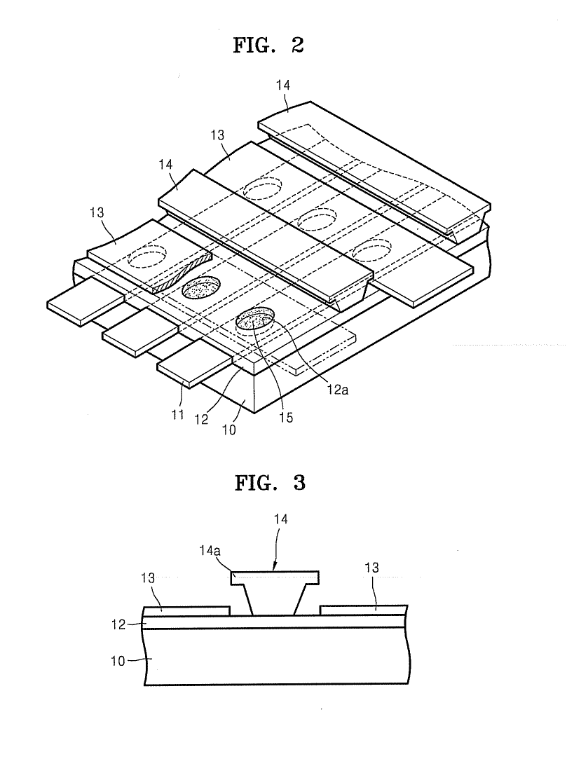

FIG. 1 is a schematic partial plan view illustrating a layout of an organic electro-luminescent display (“OELD”) according to an exemplary embodiment of the present invention. FIG. 2 is a schematic partial perspective view of the OELD of FIG. 1.

Referring to FIGS. 1 and 2, a plurality of anodes 11 are formed, on a substrate 10, in a first direction, i.e., the y direction in FIG. 1 to be substantially parallel with one another. An insulating layer 12 is formed on the anodes 11. A plurality of cathodes 13 are formed, on the insulating layer 12, in a second direction orthogonal to the first direction, i.e., the x direction in FIG. 1, to be substantially parallel with one another. Windows 12a are formed in the insulating layer 12, which insulates the anodes 11 from the cathodes 13. The windows 12a are formed at intersections between the anodes 11 and the cathodes 13. The windows 12a and filled with an organic electro-luminescent material 15. Organic electro-luminescent material may fill windows 12a entirely, or the organic electro-luminescent material may cover portions of edges of the windows 12a. As shown in FIGS. 1 and 2, the windows 12a may be ellipsoidal, for example, but is not limited thereto. Alternatively, the windows 12a may be rectangular.

Cathode separators 14, each having a predetermined width, are provided between cathodes 13 to extend in the same direction as cathodes 13. The cathode separators 14 are formed to provide strips having an inverse-trapezoidal cross-section. As shown in FIG. 3, protrusions 14a protrude from upper portions of opposing sloping sides defining the cathode separators 14. The sides of the cathode separators 14 slope inwardly with respect to the substrate 10, and the protrusions 14a protrude from the upper portions of the sides of the cathode separator 14 to a predetermined length.

The protrusions 14a protrude from the upper portions of opposing sloping sides defining the cathode separators 14 in a direction towards an adjacent cathode 13. As illustrated in FIG. 3, an edge defining an outboard edge of a protrusion 14a extends to be substantially aligned with a terminal edge of a corresponding adjacent cathode 13.

The protrusions 14a are characteristic elements of the OELD of the present invention and allow the separated cathodes 13 to be formed when a cathode material is deposited. The protrusions are further described below in the description of the method of manufacturing an OELD.

A method of manufacturing an OELD according to another exemplary embodiment of the present invention will now be schematically described.

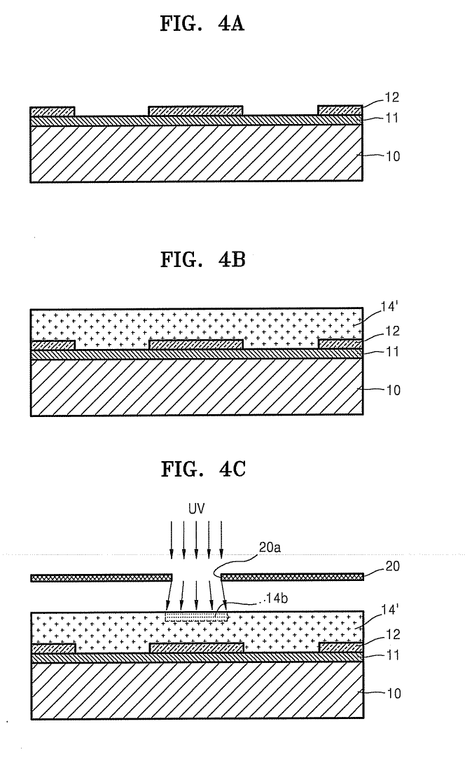

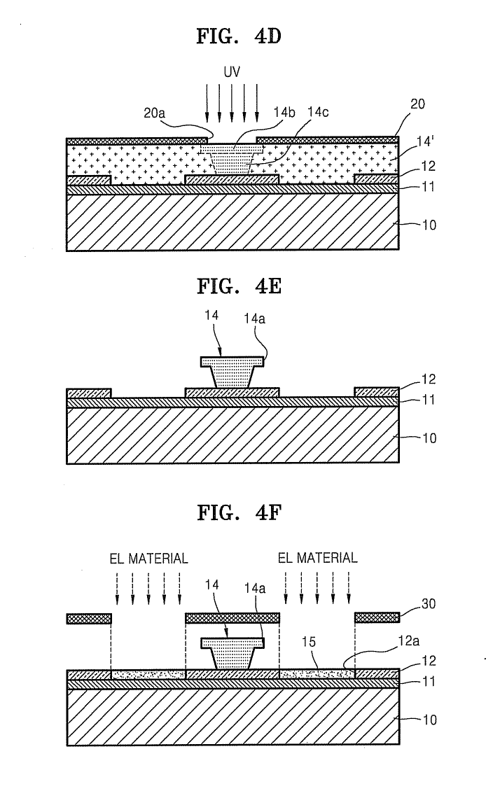

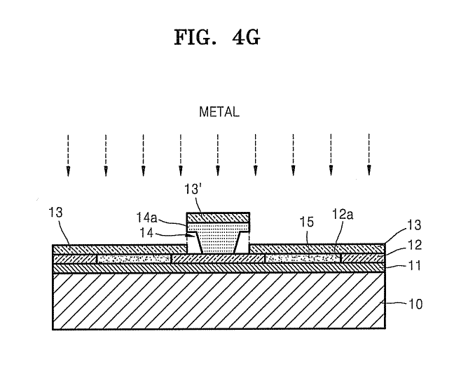

Referring to FIG. 4A, an anode 11, having a strip shape, is formed on a substrate 10, and an insulating layer 12 having windows 12a is formed on the anode 11. The windows 12a are formed using a photolithographic method. The windows 12a are then filled with an organic electro-luminescent material.

As shown in FIG. 4B, a negative photoresist such as polyimide (“PI”) or polyacryl (“PA”) is coated on the insulating layer 12 to a predetermined thickness to form a separator material 14′.

As shown in FIG. 4C, the separator material 14′ is exposed to ultraviolet rays using a mask 20 having an opening 20a with a predetermined width. As shown in FIG. 4B, the mask 20 is spaced apart from the separator material 14′ to diffract the ultraviolet rays at an edge of the opening 20a to form an upper exposed area 14b which is larger than the opening 20a. An exposure depth is selected to be smaller than a thickness of the separator material 14′ so as to expose a shallow upper portion of the unexposed separator material 14′.

As shown in FIG. 4D, the mask 20 is next disposed near unexposed separator material 14′, or preferably, is disposed on the unexposed separator material 14′. Next, the unexposed separator material 14′ is exposed to ultraviolet rays to form a lower exposed portion 14c having a narrow width. In this step, the exposure time is selected to completely expose the full cross-section of the unexposed separator material 14′ as selected by the mask 20. Since the mask 20 approaches or contacts the unexposed separator material 14′, the ultraviolet rays are diffracted inwardly by the opening 20a. Thus, a width of the exposed area is narrower in the lower portion of the separator material.

As shown in FIG. 4E, the unexposed separator material 14′ is developed to provide a desired separator 14. The separator 14 has the upper portion 14b with the wide width and the lower portion 14c with the narrow width. In particular, protrusions 14a are formed at both sides of the upper portion 14b.

As shown in FIG. 4F, an organic electro-luminescent material 15 is formed in the windows 12a of the insulating layer 12 using a selective vapor deposition method using a pattern mask 30.

As shown in FIG. 4G, a metal is deposited on the insulating layer 12, organic electro-luminescent material 15 and the separator 14, to form a cathode 13 on the insulating layer 12. The width of the upper portion 14b of the separator 14 is wider than the width of the lower portion 14c, and the protrusions 14a are formed at the upper area 14b. Thus, a material deposited on the insulating layer 12 is completely insulated from a material deposited on the separator 14. Accordingly, a plurality of cathodes 13, which are substantially parallel with one another and electrically completely insulated from one another, can be obtained.

As required for a particular application, subsequent processes can be performed to adapt the passive matrix type OELD provided by this process to a given application.

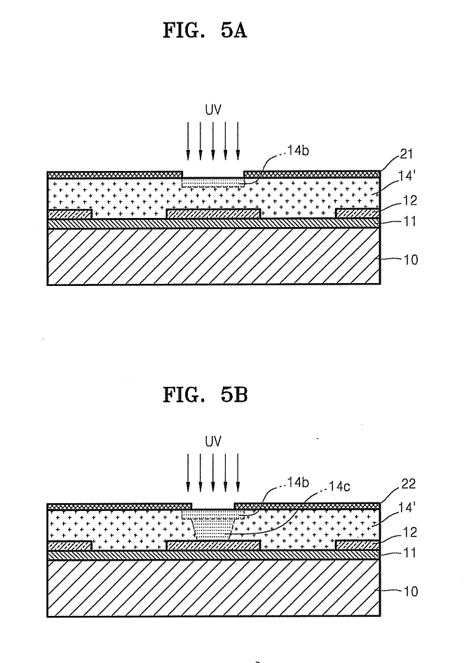

As described above, the present invention is characterized by the structure of a separator and a method of forming the separator. In terms of structure, protrusions are formed at both sides of an upper portion of the separator. In terms of method, a separator material is exposed twice to form an upper portion having a wide width and a lower portion having a narrow width. Differential exposures may use a mask and a distance between the mask and photoresist may be adjusted to adjust exposure widths, as described above. As shown in FIGS. 5A and 5B, first and second masks 21 and 22, having openings with different widths, are used to obtain a separator with a desired cross-section profile.

Referring to FIG. 5A, a photoresist layer is exposed using the first mask 21 to form an upper portion 14b.

As shown in FIG. 5B, the photoresist is exposed using the second mask 22 to form a lower portion 14c.

As described in the above exemplary embodiments, the upper portion 14b having a wide width, is formed before the lower portion 14c is formed. According to another exemplary embodiment, the lower area 14c having the narrow width, may be formed, and then the upper area 14b having the wide width may be subsequently formed. Also, as described in the above exemplary embodiments, exposure is performed twice. However, exposure may be performed two or more times in alternative exemplary embodiments.

In summary, a separator having an inverse-trapezoidal cross-section can be obtained through multiple differential exposures so as to completely separate cathodes in an OELD.

Described in the exemplary embodiments is a passive matrix type OELD, including a method of manufacturing the passive matrix type OELD, including a method of manufacturing a cathode separator therein. Protrusions 14a can be formed at both sides of an upper portion of the cathode separator 14. When metal deposition is performed, the protrusion mask portions of the insulating layer 12, adjacent to the cathode separator 14, preclude metal deposition on both sides of the lower portion 14c of the cathode separator 14. As a result, a plurality of cathodes can be formed to be substantially parallel with each other and separated from each other.

While the present invention has been particularly shown and described with reference to exemplary embodiments thereof, it will be understood by those of ordinary skill in the art that various changes in form and details may be made therein without departing from the spirit and scope of the present invention as defined by the following claims. In addition, many modifications may be made to adapt particular circumstances or materials to the teachings of the invention without departing from the essential scope thereof. Therefore, it is intended that the invention not be limited to the particular exemplary embodiments disclosed as the best mode contemplated for carrying out the invention, but that the invention will include all embodiments falling within the scope of the appended claims.

What is claimed is:

1. An organic electro-luminescent display comprising:
a substrate;
a plurality of anodes disposed on the substrate to be substantially parallel with one another in a first direction;
a plurality of cathodes disposed substantially parallel with one another in a second direction orthogonal to the plurality of anodes;
organic electro-luminescent parts provided at intersections between the anodes and the cathodes; and
a plurality of cathode separators disposed between the cathodes, each of the cathode separators having an upper portion and a lower portion, the upper portions of the cathode separators are wider than lower portions of the cathode separators,
wherein protrusions protrude from sides of the upper portions of the cathode separators.

2. The organic electro-luminescent display of claim 1, wherein the cathode separators have a first side and an opposing second side, the first and second sides inclining inwardly towards the substrate.

3. The organic electro-luminescent display of claim 2, further comprising an insulating layer disposed on the anodes, the insulating layer having a plurality of windows disposed at the intersections of the cathodes and anodes.

4. The organic electro-luminescent display of claim 3, wherein the organic electro-luminescent material is disposed within each of the windows.

5. The organic electro-luminescent display of claim 1, further comprising an insulating layer disposed on the anodes, the insulating layer having a plurality of windows disposed at the intersections of the cathodes and anodes.

6. The organic electro-luminescent display of claim 5, wherein the windows are disposed at the intersections of the cathodes and the anodes and the organic electro-luminescent material is disposed within the windows.

7. The organic electro-luminescent display of claim 1, wherein the cathode separators have a first side and a second side and one of the first and second sides inclines inwardly towards the substrate.

8. The organic electro-luminescent display of claim 1, wherein the protrusions protrude in a direction towards an adjacent cathode of the plurality of cathodes.

9. The organic electro-luminescent display of claim 8, wherein an edge defining an outboard edge of a respective protrusion extends to be substantially aligned with a terminal edge of a corresponding adjacent cathode of the plurality of cathodes.

10. A method of manufacturing an organic electro-luminescent display, comprising:
disposing a plurality of anodes on a substrate substantially parallel with one another in a first direction;
forming a photoresist on the substrate;
differentially exposing the photoresist at least two times to form cathode separators each having an upper portion and a lower portion having different widths, the width of the upper portion is wider than the width of the lower portion;
developing the photoresist to form the cathode separators; and
forming a plurality of strip-shaped cathodes between the cathode separators, the cathodes being substantially parallel with one another in a direction orthogonal to the first direction.

11. The method of claim 10, wherein the differentially exposing the photoresist includes exposing through a mask.

12. The method of claim 10, wherein the differentially exposing the photoresist includes exposure through a plurality of masks.

13. The method of claim 10, wherein the differentially exposing the photoresist includes sequentially exposing through a mask and adjusting a distance between the photoresist and the mask to form the upper portion and the lower portion.

14. The method of claim 10, wherein the differentially exposing the photoresist includes sequentially exposing through a mask, the mask is spaced apart from the photoresist to perform the exposure for forming the upper portion, and the mask approaches or contacts the photoresist layer to perform the exposure for forming the lower portion.

15. The method of claim 10, wherein the differentially exposing the photoresist includes sequentially exposing through a plurality of masks, the upper portion and the lower portion are formed using masks having openings with different widths.

16. The method of claim 15, wherein one mask is spaced apart from the photoresist layer to perform the exposure for forming the upper portion, and a second mask approaches or contacts the photoresist layer to perform the exposure for forming the lower portion.
